(19) United States
(12) Patent Application Publication
(10) Pub. No.: US 2010/0148168 A1
(43) Pub. Date: Jun. 17, 2010

(54) INTEGRATED CIRCUIT STRUCTURE

(75) Inventors: Chih-Ming Lai, Changhua County (TW); Chun-Cheng Cheng, Pingtung County (TW); Yung-Hui Yeh, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/494,304

(22) Filed: Jun. 30, 2009

(30) Foreign Application Priority Data
Dec. 12, 2008 (TW) 97148661

(51) Int. Cl. H01L 29/24

(52) U.S. Cl. 257/43; 257/E29.1

(57) ABSTRACT

An integrated circuit structure including a substrate, an insulating layer, a first transistor and a second transistor is provided. The insulating layer, the first transistor and the second transistor are disposed on the substrate. The first transistor includes a first gate, a first oxide semiconductor layer, a first source and a first drain. A portion of the first source and the first drain directly contacting the first oxide semiconductor layer is composed of a Ti-containing metal. The second transistor includes a second gate, a second oxide semiconductor layer, a second source and a second drain. A portion of the second source and the second drain directly contacting the second oxide semiconductor layer is composed of a none-Ti-containing metal. In addition, the first oxide semiconductor layer and the second oxide semiconductor layer may have different thickness or different carrier concentrations.

### CROSS-REFERENCE TO RELATED APPLICATION

This application claims the priority benefit of Taiwan application serial no. 97148661, filed Dec. 12, 2008. The entirety of the above-mentioned patent application is hereby incorporated by reference herein and made a part of specification.

### BACKGROUND

1. Technical Field

The disclosure relates to an integrated circuit structure. More particularly, the disclosure relates to an integrated circuit structure having oxide semiconductor devices.

2. Description of Related Art

Semiconductor industry is one of the fastest-growing high-tech industries. With booming development of electronic techniques and high-tech electronic industries, electronic products with more humanity and better functions are continuously developed.

In various electronic products, a flexible electronic product has a high development potential due to its characteristics of light-weight, easy-carry, flexible, etc. However, regarding a commonly used thin-film transistor, semiconductor channel layers in the thin-film transistor are mostly composed of amorphous silicon or poly silicon. Under a bended state, electrical characteristics of such thin-film transistor are influenced. For example, a conducting current generated when the thin-film transistor is turned on can be different under the bended state and a non-bended state. Therefore, the amorphous silicon or the poly silicon thin-film transistor thus is not suitable to be applied to the flexible electronic products.

An oxide semiconductor can still maintain a stable electrical characteristic under the bended state, so that it is suitable to be applied to various flexible electronic produces. However, the oxide semiconductor is generally an N-type semiconductor, and if the oxide semiconductor thin-film transistor is applied to a design of an integrated circuit structure, a gate and a drain thereof has to be connected to serve as a loading of the electronic circuit. In other words, the conventional oxide semiconductor thin-film transistor cannot be flexibly applied to the design of the integrated circuit structure.

### SUMMARY

The disclosure is directed to an integrated circuit structure formed by a plurality of oxide semiconductor thin-film transistors, wherein the oxide semiconductor thin-film transistors are function at different threshold voltages.

The disclosure is directed to an integrated circuit structure formed by a plurality of oxide semiconductor thin-film transistors having different characteristics.

The disclosure is directed to an integrated circuit structure formed by a plurality of oxide semiconductor thin-film transistors, wherein the oxide semiconductor thin-film transistors have different electrical characteristics.

The disclosure provides an integrated circuit structure including a substrate, an insulating layer, a first transistor and a second transistor. The insulating layer is disposed on the substrate. The first transistor includes a first gate, a first oxide semiconductor layer, a first source and a first drain. The first gate is disposed on the substrate, the insulating layer is disposed between the first gate and the first oxide semiconductor layer, and an area of the first gate is partially overlapped to that of the first oxide semiconductor layer. The first source and the first drain are connected to the first oxide semiconductor layer and are respectively located at two sides of the first gate. A portion of the first source and the first drain directly contacting the first oxide semiconductor layer is composed of a titanium (Ti)-containing metal. The second transistor includes a second gate, a second oxide semiconductor layer, a second source and a second drain. The second gate is disposed on the substrate, the insulating layer is disposed between the second gate and the second oxide semiconductor layer, and an area of the second gate is partially overlapped to that of the second oxide semiconductor layer. The second source and the second drain are connected to the second oxide semiconductor layer, and are respectively located at two sides of the second gate. A portion of the second source and the second drain directly contacting the second oxide semiconductor layer is composed of a none-Ti-containing metal.

The disclosure provides another integrated circuit structure including a substrate, a first insulating layer, a second insulating layer, a first transistor and a second transistor. The first insulating layer and the second insulating layer are disposed on the substrate, and the first insulating layer is located between the second insulating layer and the substrate. The first transistor includes a first gate, a first oxide semiconductor layer, a first source and a first drain. The first gate is disposed between the first insulating layer and the substrate, the first insulating layer is disposed between the first gate and the first oxide semiconductor layer, and an area of the first gate is partially overlapped to that of the first oxide semiconductor layer. The first source and the first drain are connected to the first oxide semiconductor layer and are respectively located at two sides of the first gate. The second transistor includes a second gate, a second oxide semiconductor layer, a second source and a second drain. The second gate is disposed on a side of the second insulating layer departing from the substrate, the second insulating layer is disposed between the second gate and the second oxide semiconductor layer, and an area of the second gate is partially overlapped to that of the second oxide semiconductor layer. A thickness of the first oxide semiconductor layer is different to that of the second oxide semiconductor layer. The second source and the second drain are connected to the second oxide semiconductor layer, and are respectively located at two sides of the second gate.

The disclosure provides still another integrated circuit structure including a substrate, a first insulating layer, a second insulating layer, a first transistor and a second transistor. The first insulating layer and the second insulating layer are disposed on the substrate, and the first insulating layer is located between the second insulating layer and the substrate. The first transistor includes a first gate, a first oxide semiconductor layer, a first source and a first drain. The first gate is disposed between the first insulating layer and the substrate, the first insulating layer is disposed between the first gate and the first oxide semiconductor layer, and an area of the first gate is partially overlapped to that of the first oxide semiconductor layer. The first source and the first drain are connected to the first oxide semiconductor layer and are respectively located at two sides of the first gate. The second transistor includes a second gate, a second oxide semiconductor layer, a second source and a second drain. The second gate is disposed on a side of the second insulating layer departing from the substrate, the second insulating layer is disposed between the second gate and the second oxide semiconductor layer, and an area of the second gate is partially overlapped to that of the second oxide semiconductor layer. A carrier concentration of the first oxide semiconductor layer is different to that of the second oxide semiconductor layer. The second source and the second drain are connected to the second oxide semiconductor layer, and are respectively located at two sides of the second gate.

In the present invention, at least two oxide semiconductor thin-film transistors are used to form the integrated circuit structure. Therefore, the integrated circuit structure of the disclosure can be applied to the flexible electronic products to expend an application range of the integrated circuit. In detail, to achieve different electrical characteristics of the oxide semiconductor thin-film transistors, the Ti-containing metal is directly contacted to the oxide semiconductor layer to form the source and drain of a part of the transistors in the integrated circuit structure, or the thickness and oxygen concentration of the oxide semiconductor layer of a part of the transistors in the integrated circuit structure are changed.

In order to make the aforementioned and features of the disclosure comprehensible, a embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of an integrate circuit structure according to a first embodiment of the present invention.

FIG. 2 is a cross-sectional view of an integrated circuit structure according to a second embodiment of the present invention.

FIG. 3 is a cross-sectional view of an integrated circuit structure according to a third embodiment of the present invention.

FIG. 4 is a cross-sectional view of an integrated circuit structure according to a fourth embodiment of the present invention.

### DESCRIPTION OF EMBODIMENTS

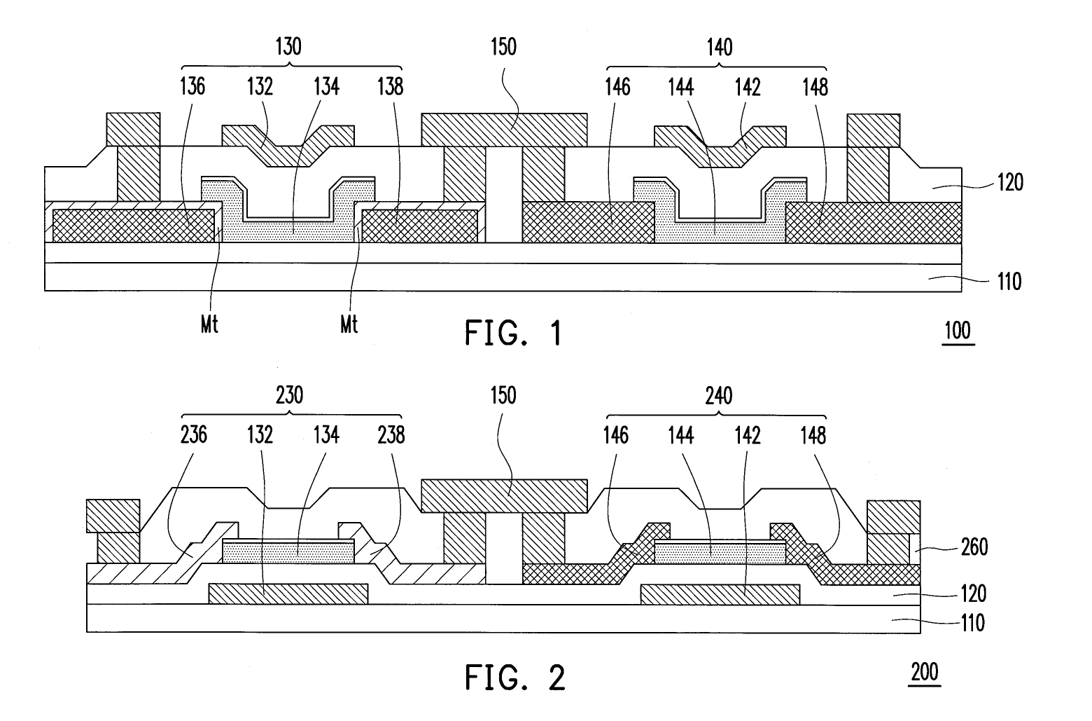

FIG. 1 is a cross-sectional view of an integrate circuit structure according to a first embodiment of the present invention. Referring to FIG. 1, the integrated circuit structure 100 includes a substrate 110, an insulating layer 120, a first transistor 130 and a second transistor 140. The insulating layer 120 is disposed on the substrate 110. The first transistor 130 includes a first gate 132, a first oxide semiconductor layer 134, a first source 136 and a first drain 138. Moreover, the second transistor 140 includes a first gate 142, a second semiconductor layer 144, a second source 146 and a second drain 148.

The first gate 132 is disposed on the substrate 110, the insulating layer 120 is disposed between the first gate 132 and the first oxide semiconductor layer 134, and an area of the first gate 132 is partially overlapped to that of the first oxide semiconductor layer 134. The first source 136 and the first drain 138 are connected to the first oxide semiconductor layer 134 and are respectively located at two sides of the first gate 132. A portion of the first source 136 and the first drain 138 directly contacting the first oxide semiconductor layer 134 is composed of a Ti-containing metal. In the present embodiment, the first gate 132 is located on a side of the insulating layer 120 departing from the substrate, and the insulating layer 120 is disposed between the substrate 110 and the first gate 132. In other words, the first transistor 130 is a top-gate thin-film transistor.

Meanwhile, configurations of the second gate 142, the second oxide semiconductor layer 144, the second source 146 and the second drain 148 are the same as that of the devices in the first transistor 130. Namely, the second gate 142 can also be disposed on a side of the insulating layer 120 departing from the substrate 110, and the insulating layer 120 is disposed between the substrate 110 and the second gate 142. It should be noted that a portion of the second source 146 and the second drain 148 directly contacting the second oxide semiconductor layer 144 is composed of a none-Ti-containing metal. Moreover, the integrated circuit structure 100 further includes a connecting metal 150 connected between the first transistor 130 and the second transistor 140. Namely, the first transistor 130 and the second transistor 140 are electrically connected.

According to FIG. 1, the first source 136 and the first drain 138 of the present embodiment are, for example, formed by a multi-layer metal structure, wherein a structure layer Mt wrapping the outmost layer thereof is a Ti-containing metal layer. Moreover, the second source 146 and the second drain 148 are, for example, formed by a single-layer structure, and a material thereof is a none-Ti-containing metal. Certainly, the disclosure is not limited thereto, and in other embodiments, the first source 136 and the first drain 138 can be formed by a single-layer Ti-containing metal material, and the second source 146 and the second drain 148 can be formed by the multi-layer metal structure.

In the present embodiment, the material of the first source 136 and the first drain 138 of the single-layer structure design can be Ti or titanium nitride (TiN), etc., and the material for a multi-layer structure design thereof can be Ti/Al laminated layer, Ti/Au laminated layer or Ti/Al/Ti laminated layer, etc. Moreover, the material of the second source 146 and the second drain 148 can be indium tin oxide (ITO), indium zinc oxide (IZO), molybdenum (Mo), chromium (Cr), aluminium (Al), aurum (Au), tungsten-molybdenum (MoW) alloy or alloys thereof. In an actual application, a portion of the first source 136 and the first drain 138 directly contacting the first oxide semiconductor layer 134 is composed of the Ti-containing metal, and a portion of the second source 146 and the second drain 148 directly contacting the second oxide semiconductor layer 144 is composed of the none-Ti-containing metal, so as to form the integrated circuit 100 of the present invention. Certainly, the disclosure is not limited to the aforementioned materials, and other conductive materials can also be applied.

According to the electrical characteristics presented when the Ti metal contacts the oxide semiconductor, a design that the first oxide semiconductor layer 134 contacts the structure layer Mt results in a fact that a threshold voltage of the first transistor 130 is decreased to a negative value. The second source 146 and the second drain 148 contacting the second semiconductor layer 144 are composed of the non-Ti-containing metal, so that the threshold voltage of the second transistor 140 is a positive value. Therefore, the first transistor 130 and the second transistor 140 can be respectively regarded as a depletion-type transistor and an enhancement-type transistor.

In other words, performance of the electrical characteristic presented when the Ti-containing metal material contacts the oxide semiconductor is different to that of the electrical characteristic presented when other metal materials contact the oxide semiconductor, so that the first transistor 130 and the second transistor 140 can present different electrical characteristics. Therefore, utilization of the two types of the oxide semiconductor thin-film transistors can satisfy demands of various circuit designs. Accordingly, a problem that the conventional oxide semiconductor thin-film transistor cannot be applied to the integrated circuit design can be resolved.

Furthermore, when a thickness of the oxide semiconductor layer (134 or 144) is relatively great, the threshold voltage of the transistor (130 or 140) is relatively great, and conversely the threshold voltage of the transistor (130 or 140) is decreased. Moreover, if the oxide semiconductor layer (134 or 144) has a relatively great carrier concentration, the threshold voltage of the transistor (130 or 140) can be decreased. Conversely, if the oxide semiconductor layer (134 or 144) has a relatively small carrier concentration, the threshold voltage of the transistor (130 or 140) is increased. In other words, besides by selecting different metal materials to contact the oxide semiconductor thin-film, the electrical characteristics of the first transistor 130 and the second transistor 140 can also be adjusted according to other methods. Therefore, in the present embodiment, the thickness of the first oxide semiconductor layer 134 can be different to that of the second oxide semiconductor layer 144. Alternatively, the carrier concentration of the first oxide semiconductor layer 134 can be different to that of the second oxide semiconductor layer 144.

Moreover, though in the present embodiment, the two transistors 130 and 140 are electrically connected to form the integrated circuit structure 100, in the other embodiments, more than two oxide semiconductor thin-film transistors having different electrical characteristics can be connected to form the needed integrated circuit structure. Namely, according to different design and performance requirements of the circuit, different number of the first transistor 130 and the second transistor 140 can be configured on the substrate 110 based on different connecting approaches.

It should be noted that the material of the first oxide semiconductor layer 134 and the second oxide semiconductor layer 144 includes oxide materials such as zinc oxide, indium gallium zinc oxide or indium zinc tin oxide, etc. The oxide semiconductor thin-film transistor fabricated by such oxide materials is less sensitive to a flexible state, so that in the integrated circuit structure 100 of the present embodiment, a flexible material can be selected to serve as the substrate 110, so as to expend the application range of the integrated circuit structure 100. The commonly used flexible materials are, for example, polyimide, polyethylene naphthalate (PEN) and polyethylene terephthalate (PET). Temperature endurances of these flexible materials are relatively poor, so that high-temperature processes such as ion implant, activation and diffusion, etc. performed during fabrication of the conventional integrated circuit can deform the substrate 110 to lower a production yield. The first transistor 130 and the second transistor 140 may have different electrical characteristics only by selecting different metal materials, and none high-temperature process is required for changing the electrical characteristics of the two transistors 130 and 140. Therefore, when the integrated circuit structure 100 applies the flexible material to serve as the substrate 110, damage of the substrate 110 during the fabrication process can be avoided.

In the present embodiment, the Ti-containing metal of the first transistor 130 includes Ti or Ti alloy. Namely, the present embodiment is not limited to just use the pure Ti metal for directly contacting the first oxide semiconductor layer 134, but the Ti alloy can also be applied. However, the aforementioned materials are only used as an example, which is not used for limiting the present invention. For example, the materials of electrodes in the integrated circuit structure 100 include various conductive materials such as ITO, Mo, Cr and Al, etc.

FIG. 2 is a cross-sectional view of an integrated circuit structure according to a second embodiment of the present invention. Referring to FIG. 2, components of the integrated circuit structure 200 are approximately similar to that of the integrated circuit structure 100, and the same reference numerals denote the same components. A difference therebetween is that a first transistor 230 and a second transistor 240 of the integrated circuit structure are all bottom-gate thin-film transistors. Moreover, the first source 236 and the first drain 238 have the single-layer metal structure, and the material of a first source 236 and a first drain 238 is Ti-containing metal such as Ti, or Ti alloy, etc. The material of the second source 146 and the second drain 148 is none-Ti-containing material.

In detail, according to the structure, the first gate 132 of the present embodiment is located between the substrate 110 and the insulating layer 120. Moreover, the second gate 142 is also located between the substrate 110 and the insulating layer 120. In addition, to protect the first transistor 230 and the second transistor 240, the integrated circuit structure 200 further includes a passivation layer 260 covering the first transistor 230 and the second transistor 240. The connecting metal 150 is, for example, disposed on the passivation layer 260.

In the present embodiment, the electrical characteristics of the first transistor 230 and the second transistor 240 can be changed by selecting different metal materials, so that one of the first transistor 230 and the second transistor 240 is the depletion-type thin-film transistor and another one is the enhancement-type thin-film transistor. Namely, if the first transistor 230 and the second transistor 240 are electrically connected, an integrated circuit with specific performance is formed. Here, one first transistor 230 and one second transistor 240 are connected to form the integrated circuit structure 200, though the disclosure is not limited thereto. The integrated circuit 200 can be formed by different number of the first transistor 230 and the second transistor 240 according to different requirements, so as to achieve specific circuit designs.

Since the oxide semiconductor thin-film transistor has a high endurance in the flexible state, the integrated circuit structure 200 can still be normally operated under the flexible state, namely, the electrical characteristics of the components therein are not changed. Therefore, the flexible material can be selected to fabricate the substrate 110, so as to further apply the integrated circuit structure 200 to the flexible electronic products. Therefore, application of the integrated circuit structure can be expended. Moreover, the integrated circuit structure 200 can also has the characteristics as that of the integrated circuit structure 100.

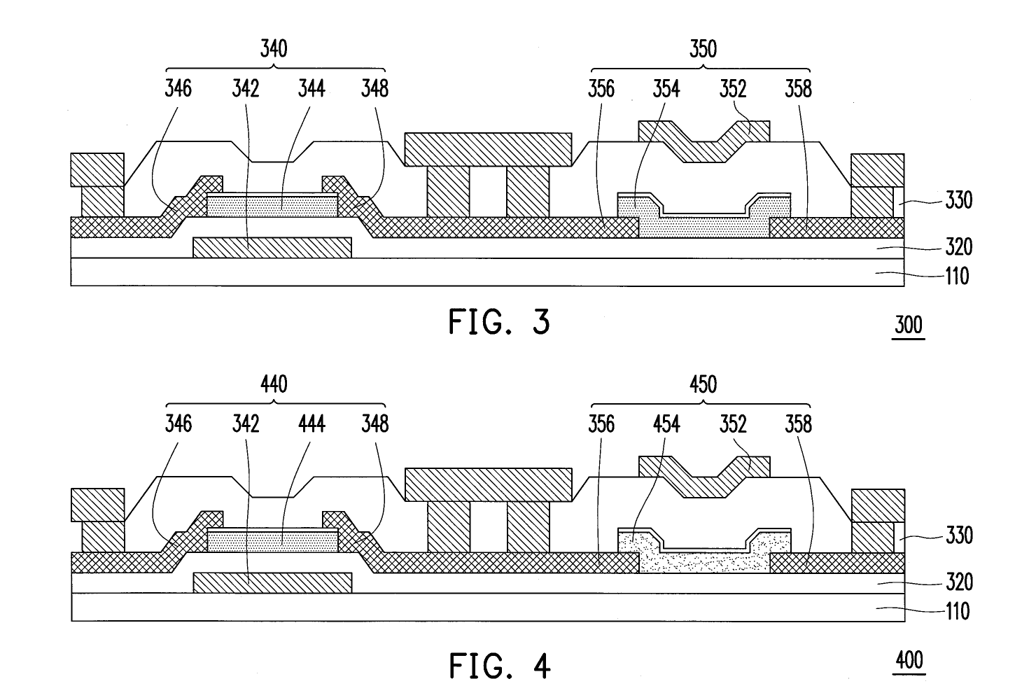

FIG. 3 is a cross-sectional view of an integrated circuit structure according to a third embodiment of the present invention. Referring to FIG. 3, the integrated circuit structure 300 includes a substrate 110, a first insulating layer 320, a second insulating layer 330, a first transistor 340 and a second transistor 350. The first insulating layer 320 and the second insulating layer 330 are disposed on the substrate 110, and the first insulating layer 320 is located between the second insulating layer 330 and the substrate 110. The first transistor 340 includes a first gate 342, a first oxide semiconductor layer 344, a first source 346 and a first drain 348. The second transistor 350 includes a second gate 352, a second oxide semiconductor layer 354, a second source 356 and a second drain 358.

In detail, the first gate 342 is disposed between the first insulating layer 320 and the substrate 110, the first insulating layer 320 is disposed between the first gate 342 and the first oxide semiconductor layer 344, and an area of the first gate 342 is partially overlapped to that of the first oxide semiconductor layer 344. The first source 346 and the first drain 348 are connected to the first oxide semiconductor layer 344, and are respectively located at two sides of the first gate 342. Namely, the first transistor 340 is the bottom-gate thin-film transistor.

Moreover, the second gate 352 is disposed on the second insulating layer 330 at a side departing from the substrate 110, the second insulating layer 330 is disposed between the second gate 352 and the second oxide semiconductor layer 354, and an area of the second gate 352 is partially overlapped to that of the second oxide semiconductor layer 354. The second source 356 and the second drain 358 are connected to the second oxide semiconductor layer 354, and are respectively located at two sides of the second gate 352. It should be noted that a thickness of the first oxide semiconductor layer 344 is different to that of the second oxide semiconductor layer 354. Moreover, the second transistor 350 is the top-gate thin-film transistor according to the structure thereof.

Generally, a conductivity of the oxide semiconductor layer is varied along with the thickness thereof, especially when the oxide semiconductor layer is applied to the thin-film transistor. For example, in the oxide semiconductor thin-film transistor, if the thickness of the oxide semiconductor layer is greater than 50 nm, the threshold voltage of the oxide semiconductor thin-film transistor is less than 0V. Conversely, if the thickness of the oxide semiconductor layer is less than 50 nm, the threshold voltage of the oxide semiconductor thin-film transistor is greater than 0V. Namely, in the integrated circuit structure 300 of the present embodiment, if the thin-film transistors with different threshold voltages are required to be applied, the first oxide semiconductor layer 344 and the second oxide semiconductor layer 354 having different thickness can be configured.

For example, if the thickness of the first oxide semiconductor layer 344 is less than 50 nm, and the thickness of the second oxide semiconductor 354 is greater than 50 nm, the first transistor 340 is then the enhancement-type thin-film transistor, and the second transistor 350 is the depletion-type thin-film transistor. By connecting the enhancement-type transistor and the depletion-type transistor, the integrated circuit structure 300 can perform various functions. Certainly, the thickness of the first oxide semiconductor layer 344 can be greater than 50 nm, and the thickness of the second oxide semiconductor layer 354 can also be less than 50 nm.

In the present embodiment, the first oxide semiconductor layer 344 and the second oxide semiconductor layer 354 have different thickness, so that the first transistor 340 and the second transistor 350 may have different electrical characteristics. Moreover, by selecting different metal materials, the electrical characteristics of the first transistor 340 and the second transistor 350 can be different. In detail, if the thickness of the first oxide semiconductor layer 344 is less than 50 nm, and the thickness of the second oxide semiconductor layer 354 is greater than 50 nm, the first transistor 340 is then the enhancement-type thin-film transistor, and the second transistor 350 is the depletion-type thin-film transistor. Now, in the present embodiment, a portion of the first source 346 and the first drain 348 directly contacting the first oxide semiconductor layer 344 can further be the none-Ti-containing metal material, and a portion of the second source 356 and the second drain 358 directly contacting the second oxide semiconductor layer 354 can be the Ti-containing metal material.

Moreover, if the thickness of the first oxide semiconductor layer 344 is greater than 50 nm, and the thickness of the second oxide semiconductor layer 354 is less than 50 nm, the first transistor 340 is then the depletion-type thin-film transistor, and the second transistor 350 is the enhancement-type thin-film transistor. Now, a portion of the first source 346 and the first drain 348 directly contacting the first oxide semiconductor layer 344 can further be the Ti-containing metal material, and a portion of the second source 356 and the second drain 358 directly contacting the second oxide semiconductor layer 354 can be the none-Ti-containing metal material.

In other words, in the present embodiment, the electrical characteristics of the first transistor 340 and the second transistor 350 can not only be adjusted according to the thickness of the oxide semiconductor layers, but can also be adjusted by changing the materials of the first source 346, the first drain 348, the second source 356 and the second drain 358. Similarly, in the first embodiment and the second embodiment, the thickness of the first oxide semiconductor layer 134 and the second oxide semiconductor layer 144 can also be adjusted, so as to achieve different electrical characteristics of the first transistors 130 and 230, and the second transistors 140 and 240.

Besides, none high-temperature process is required for changing the electrical characteristics of the first transistor 340 and the second transistor 350 in the present embodiment. Therefore, when the flexible material is applied to fabricate the substrate 110, the integrated circuit structure 300 can still maintain a good quality. Namely, the integrated circuit 300 can be applied to the flexible electronic products.

FIG. 4 is a cross-sectional view of an integrated circuit structure according to a fourth embodiment of the present invention. Referring to FIG. 4, the integrated circuit structure 400 is approximately similar to the integrated circuit structure 300, and the same reference numerals denote the same components. The integrated circuit structure 400 includes a substrate 110, a first insulating layer 320, a second insulating layer 330, a first transistor 440 and a second transistor 450. The first transistor 440 includes a first gate 342, a first oxide semiconductor layer 444, a first source 346 and a first drain 348. The second transistor 450 includes a second gate 352, a second oxide semiconductor layer 454, a second source 356 and a second drain 358. In the present embodiment, the carrier concentrations of the first oxide semiconductor layer 444 and the second oxide semiconductor layer 454 are different.

The first oxide semiconductor layer 444 and the second oxide semiconductor layer 454 are generally formed based on a sputtering treatment. If a proportion of sputtering gasses is adjusted during the sputtering process, compositions and characteristics of the first oxide semiconductor layer 444 and the second oxide semiconductor layer 454 are then changed. During the sputtering process of the oxide semiconductor, the argon gas is generally used as the sputtering gas, and meanwhile the oxygen is used as a reactive gas. When a flux of the oxygen is changed, the carrier concentration of the oxide semiconductor thin-film is accordingly changed to present a different characteristic.

For example, during the fabrication process of the oxide semiconductor layer (444 or 454), an indium gallium zinc oxide target can be applied. When a proportion of the indium, gallium, and zinc is about 1:1:1, a flux ratio of the oxygen and the argon can be respectively O₂/(Ar+O₂)>0.1 and O₂/(Ar+O₂)<0.1. The carrier concentration of the oxide semiconductor layer formed according to the former condition is approximately less than 10¹⁶/cm³, and the carrier concentration of the oxide semiconductor layer formed according to the latter condition is, for example, greater than 10¹⁷/cm³. Therefore, if the first oxide semiconductor layer 444 and the second oxide semiconductor layer 454 are fabricated according to different gas conditions, the first transistor 440 and the second transistor 450 then have different electrical characteristics. The aforementioned flux ratio of the oxygen and the argon gas is only used as an example. During an actual application, different gas conditions can be selected according to different compositions of the target and different composition ratios of the target, so as to adjust the carrier concentrations of the first oxide semiconductor layer 444 and the second oxide semiconductor layer 454.

In the present embodiment, if the first transistor 440 is designed to be the enhancement-type thin-film transistor, and the second transistor 450 is designed to be the depletion-type transistor, the first oxide semiconductor layer 444 then can be fabricated under a fabrication condition of relatively high oxygen flux, and the second oxide semiconductor layer 454 can be fabricated under a fabrication condition of relatively low oxygen flux. Conversely, inversed fabrication conditions can be used to respectively fabricate the first oxide semiconductor layer 444 and the second oxide semiconductor layer 454.

During the actual application, to avoid an influence of the characteristics of the first oxide semiconductor layer 444 and the second oxide semiconductor layer 454 caused by different fabrication conditions, when the first transistor 440 and the second transistor 450 are fabricated, a fabrication step with relatively high oxygen flux is performed first, and a fabrication step with relatively low oxygen flux is performed later. Certainly, the disclosure is not limited thereto, and in other embodiments, a sequence of the fabrication steps can be arranged according to different fabrication requirements.

Moreover, to further adjust the electrical characteristics of the first transistor 440 and the second transistor 450, the first source 346, the first drain 348, the second source 356 and the second drain 358 can be respectively fabricated by applying different materials or according to different structure designs. For example, if the first transistor 440 is designed to be the enhancement-type thin-film transistor, and the second transistor 450 is designed to be the depletion-type transistor, the first source 346 and the first drain 348 can be fabricated by using the none-Ti-containing metal, and the second source 356 and the second drain 358 can be fabricated by using the Ti-containing metal. Namely, a portion of the second source 356 and the second drain 358 directly contacting the second oxide semiconductor layer 454 is composed of the Ti-containing metal. Meanwhile, a portion of the first source 346 and the first drain 348 directly contacting the first oxide semiconductor layer 444 is composed of the none-Ti-containing metal.

Certainly, if the first transistor 440 is designed to be the depletion-type thin-film transistor, and the second transistor 450 is designed to be the enhancement-type transistor, a portion of the first source 346 and the first drain 348 directly contacting the first oxide semiconductor layer 444 is then composed of the Ti-containing metal, and a portion of the second source 356 and the second drain 358 directly contacting the second oxide semiconductor layer 454 is composed of the none-Ti-containing metal.

Furthermore, besides by controlling the fabrication conditions to achieve different electrical characteristics of the first transistor 440 and the second transistor 450, the thickness of the first oxide semiconductor layer 444 and the second oxide semiconductor layer 454 can be simultaneously adjusted. Namely, the electrical characteristics of the first transistor 440 and the second transistor 450 not only can be changed by adjusting the fabrication conditions, but can also be further modulated by varying the thickness of the oxide semiconductor layer and selecting different metal materials for the source and drain electrodes. Certainly, the adjustment method of the fabrication conditions provided by the present embodiment can also be applied to the first, the second and the third embodiments set forth before.

In summary, in the present invention, the transistors with different electrical characteristics can be achieved by selecting different electrode materials, changing the thickness of the oxide semiconductor layers and changing the fabrication conditions of the oxide semiconductor layers. Therefore, the oxide semiconductor thin-film transistors can be applied to the integrated circuit. Since an endurance of the oxide semiconductor thin-film transistor in the flexible state is relatively great, it can be applied to flexible electronic products. In other words, the integrated circuit structure of the disclosure can be applied to the flexible electronic products and may have a good quality.

It will be apparent to those skilled in the art that various modifications and variations can be made to the structure of the disclosure without departing from the scope or spirit of the invention. In view of the foregoing, it is intended that the disclosure cover modifications and variations of this invention provided they fall within the scope of the following claims and their equivalents.

What is claimed is:

1. An integrated circuit structure, at least comprising:
a substrate;
an insulating layer, disposed on the substrate;
a first transistor, at least comprising:
a first gate, disposed on the substrate;
a first oxide semiconductor layer, the insulating layer being disposed between the first gate and the first oxide semiconductor layer, and an area of the first gate being partially overlapped to that of the first oxide semiconductor layer;
a first source, connected to the first oxide semiconductor layer;
a first drain, connected to the first oxide semiconductor layer, and the first source and the first drain being respectively located at two sides of the first gate, wherein a portion of the first source and the first drain directly contacting the first oxide semiconductor layer is composed of a titanium (Ti)-containing metal.
a second transistor, electrically connected to the first transistor, and comprising:
a second gate, disposed on the substrate;
a second oxide semiconductor layer, the insulating layer being disposed between the second gate and the second oxide semiconductor layer, and an area of the second gate being partially overlapped to that of the second oxide semiconductor layer;
a second source, connected to the second oxide semiconductor layer; and
a second drain, connected to the second oxide semiconductor layer, and the second source and the second drain being respectively located at two sides of the second gate, wherein a portion of the second source and the second drain directly contacting the second oxide semiconductor layer is composed of a none-Ti-containing metal.

2. The integrated circuit structure as claimed in claim 1, wherein a thickness of the first oxide semiconductor layer is different to that of the second oxide semiconductor layer.

3. The integrated circuit structure as claimed in claim 1, wherein a carrier concentration of the first oxide semiconductor layer is different to that of the second oxide semiconductor layer.

4. The integrated circuit structure as claimed in claim 1, wherein the first gate is located between the substrate and the insulating layer.

5. The integrated circuit structure as claimed in claim 4, wherein the second gate is located between the substrate and the insulating layer.

6. The integrated circuit structure as claimed in claim 1, wherein the first gate is located on a side of the insulating layer departing from the substrate, and the insulating layer is located between the substrate and the first gate.

7. The integrated circuit structure as claimed in claim 6, wherein the second gate is located on a side of the insulating layer departing from the substrate, and the insulating layer is located between the substrate and the second gate.

8. The integrated circuit structure as claimed in claim 1, wherein the Ti-containing metal comprises Ti or Ti alloy.

9. The integrated circuit structure as claimed in claim 1 further comprising a connecting metal connected between the first transistor and the second transistor.

10. The integrated circuit structure as claimed in claim 1, wherein a material of the first oxide semiconductor layer and the second oxide semiconductor layer comprises zinc oxide, indium gallium zinc oxide or indium zinc tin oxide.

11. The integrated circuit structure as claimed in claim 1, wherein the substrate is a flexible substrate.

12. The integrated circuit structure as claimed in claim 11, wherein a material of the flexible substrate comprises polyimide, polyethylene naphthalate (PEN) or polyethylene terephthalate (PET).

13. An integrated circuit structure, at least comprising:
a substrate;
a first insulating layer, disposed on the substrate;
a second insulating layer, disposed on the substrate, and the first insulating layer being located between the second insulating layer and the substrate;
a first transistor, at least comprising:
a first gate, disposed between the first insulating layer and the substrate;
a first oxide semiconductor layer, the first insulating layer being disposed between the first gate and the first oxide semiconductor layer, and an area of the first gate being partially overlapped to that of the first oxide semiconductor layer;
a first source, connected to the first oxide semiconductor layer;
a first drain, connected to the first oxide semiconductor layer, and the first source and the first drain being respectively located at two sides of the first gate;
a second transistor, electrically connected to the first transistor, and comprising:
a second gate, disposed on the second insulating layer at a side departing from the substrate;
a second oxide semiconductor layer, the second insulating layer being disposed between the second gate and the second oxide semiconductor layer, and an area of the second gate being partially overlapped to that of the second oxide semiconductor layer, wherein a thickness of the first oxide semiconductor layer is different to that of the second oxide semiconductor layer;
a second source, connected to the second oxide semiconductor layer; and
a second drain, connected to the second oxide semiconductor layer, and the second source and the second drain being respectively located at two sides of the second gate.

14. The integrated circuit structure as claimed in claim 13 further comprising a connecting metal connected between the first transistor and the second transistor.

15. The integrated circuit structure as claimed in claim 13, wherein a material of the first oxide semiconductor layer and the second oxide semiconductor layer comprises zinc oxide, indium gallium zinc oxide or indium zinc tin oxide.

16. The integrated circuit structure as claimed in claim 13, wherein the substrate is a flexible substrate.

17. The integrated circuit structure as claimed in claim 16, wherein a material of the flexible substrate comprises polyimide, PEN or PET.

18. The integrated circuit structure as claimed in claim 13, wherein a thickness of the first oxide semiconductor layer is greater than 50 nm, and a thickness of the second oxide semiconductor layer is less than 50 nm.

19. The integrated circuit structure as claimed in claim 13, wherein a thickness of the first oxide semiconductor layer is less than 50 nm, and a thickness of the second oxide semiconductor layer is greater than 50 nm.

20. The integrated circuit structure as claimed in claim 13, wherein a carrier concentration of the first oxide semiconductor layer is different to that of the second oxide semiconductor layer.

21. The integrated circuit structure as claimed in claim 13, wherein a portion of the first source and the first drain directly contacting the first oxide semiconductor layer is composed of a Ti-containing metal, and a portion of the second source and the second drain directly contacting the second oxide semiconductor layer is composed of a none-Ti-containing metal.

22. The integrated circuit structure as claimed in claim 13, wherein a portion of the first source and the first drain directly contacting the first oxide semiconductor layer is composed of a none-Ti-containing metal, and a portion of the second source and the second drain directly contacting the second oxide semiconductor layer is composed of a Ti-containing metal.

23. An integrated circuit structure, at least comprising:
a substrate;
a first insulating layer, disposed on the substrate;
a second insulating layer, disposed on the substrate, and the first insulating layer being located between the second insulating layer and the substrate;
a first transistor, at least comprising:
a first gate, disposed between the first insulating layer and the substrate;
a first oxide semiconductor layer, the first insulating layer being disposed between the first gate and the first oxide semiconductor layer, and an area of the first gate being partially overlapped to that of the first oxide semiconductor layer;
a first source, connected to the first oxide semiconductor layer;
a first drain, connected to the first oxide semiconductor layer, and the first source and the first drain being respectively located at two sides of the first gate;
a second transistor, electrically connected to the first transistor, and comprising:
a second gate, disposed on the second insulating layer at a side departing from the substrate;
a second oxide semiconductor layer, the second insulating layer being disposed between the second gate and the second oxide semiconductor layer, and an area of the second gate being partially overlapped to that of the second oxide semiconductor layer, wherein a carrier concentration of the first oxide semiconductor layer is different to that of the second oxide semiconductor layer;
a second source, connected to the second oxide semiconductor layer; and
a second drain, connected to the second oxide semiconductor layer, and the second source and the second drain being respectively located at two sides of the second gate.

24. The integrated circuit structure as claimed in claim 23 further comprising a connecting metal connected between the first transistor and the second transistor.

25. The integrated circuit structure as claimed in claim 23, wherein a material of the first oxide semiconductor layer and the second oxide semiconductor layer comprises zinc oxide, indium gallium zinc oxide or indium zinc tin oxide.

26. The integrated circuit structure as claimed in claim 23, wherein the substrate is a flexible substrate.

27. The integrated circuit structure as claimed in claim 26, wherein a material of the flexible substrate comprises polyimide, PEN or PET.

28. The integrated circuit structure as claimed in claim 23, wherein a portion of the first source and the first drain directly contacting the first oxide semiconductor layer is composed of a Ti-containing metal, and a portion of the second source and the second drain directly contacting the second oxide semiconductor layer is composed of a none-Ti-containing metal.

29. The integrated circuit structure as claimed in claim 28, wherein a thickness of the first oxide semiconductor layer is different to that of the second oxide semiconductor layer.

30. The integrated circuit structure as claimed in claim 28, wherein a thickness of the first oxide semiconductor layer is greater than 50 nm, and a thickness of the second oxide semiconductor layer is less than 50 nm.

31. The integrated circuit structure as claimed in claim 23, wherein a portion of the first source and the first drain directly contacting the first oxide semiconductor layer is composed of a none-Ti-containing metal, and a portion of the second source and the second drain directly contacting the second oxide semiconductor layer is composed of a Ti-containing metal.

32. The integrated circuit structure as claimed in claim 31, wherein a thickness of the first oxide semiconductor layer is different to that of the second oxide semiconductor layer.

33. The integrated circuit structure as claimed in claim 31, wherein a thickness of the first oxide semiconductor layer is less than 50 nm, and a thickness of the second oxide semiconductor layer is greater than 50 nm.
